(19) United States
(12) Patent Application Publication
(10) Pub. No.: US 2026/0302027 A1
(43) Pub. Date: Oct. 1, 2026

(54) IRON CORE-EQUIPPED SUPERCONDUCTING MAGNET, ACCELERATOR INCLUDING IRON CORE-EQUIPPED SUPERCONDUCTING MAGNET, AND PARTICLE BEAM THERAPY APPARATUS INCLUDING ACCELERATOR

(71) Applicant: Hitachi High-Tech Corporation, Tokyo (JP)

(72) Inventor: Hiroyuki WATANABE, Tokyo (JP)

(21) Appl. No.: 19/112,289

(22) PCT Filed: Jul. 26, 2023
(86) PCT No.: PCT/JP2023/027395

§ 371 Date: Mar. 17, 2025

(30) Foreign Application Priority Data
Oct. 20, 2022 (JP) 2022-168707

(51) Int. Cl. H01F 6/06; H01F 3/10; H01F 6/04; H05H 7/04; H05K 9/00

(52) U.S. Cl. CPC H01F 6/06; H01F 3/10; H01F 6/04; H05H 7/04; H05K 9/0075; H05H 2277/11

(57) ABSTRACT

Provided is an iron core-equipped superconducting magnet capable of efficiently protecting a refrigerator port portion. An iron core-equipped superconducting magnet 11 includes: iron cores 12 and 13; a coil portion vacuum chamber 20 that is provided inside the iron core and in which a main coil 23 is built; and a refrigerator port portion 30 provided in the iron core, the refrigerator port portion including a body portion 31 provided to be exposed on a surface of the iron core, and a cold head portion 32 extending from the body portion through the iron core to the main coil and connected to the main coil. A magnetic shield portion 202 through which the cold head portion passes is provided between the body portion and the cold head portion.

### TECHNICAL FIELD

The present invention relates to an iron core-equipped superconducting magnet, an accelerator including the iron core-equipped superconducting magnet, and a particle beam therapy apparatus including the accelerator.

### BACKGROUND ART

A high-energy ion beam used in particle beam therapy, physical experiments, or the like is generated using an accelerator. For example, a cyclotron, a synchrotron, a synchrocyclotron, and the like are known as accelerators that obtain a beam having kinetic energy per nucleus of about 200 MeV (PTL 1 and PTL 2).

PTL 1 discloses that, in a circular accelerator that accelerates a charged particle beam while increasing a trajectory radius by applying a radio frequency wave in a main magnetic field, the accelerator extracts a charged particle beam by applying a radio frequency wave having a frequency different from that of the radio frequency wave used for acceleration to the charged particle beam.

In an accelerator using an iron core-equipped superconducting magnet such as a superconducting cyclotron or a superconducting synchrocyclotron, a plurality of refrigerators are provided to cool a main coil to a cryogenic temperature (PTL 2). In PTL 2, a cryocooler is provided in a radial direction.

PTL 3 discloses a refrigerator-equipped superconducting magnet device including a vacuum chamber that contains a superconducting coil and a magnetic shield that prevents external leakage of a magnetic field generated by the superconducting coil. In PTL 3, a member constituting the vacuum chamber and the magnetic shield are integrally formed (see paragraphs [0033] and [0043] in PTL 3).

### CITATION LIST

### Patent Literature

PTL 1: JP2019-133745A

PTL 2: Japanese Patent No. 5481070

PTL 3: JP2004-281469A

### SUMMARY OF THE INVENTION

### Technical Problem

In view of constraint conditions and the like in installing an accelerator, it is conceivable to install a refrigerator directly above or directly below a main coil. In this case, a through hole is formed from an upper surface or a lower surface of an iron core toward the main coil inside the iron core, and a refrigerator port is inserted into the through hole and brought into contact with the main coil.

Since a direction switching valve, an electric motor, and the like are accommodated in a body portion of the refrigerator port, it is necessary to provide protection with a magnetic shield so that leakage flux from the superconducting coil does not adversely affect an electric device such as the electric motor. A configuration in which substantially the entire surface of the iron core is covered with a magnetic material to shield the iron core is also conceivable, but in this case, the cost increases.

On the other hand, when maintaining an iron core-equipped superconducting magnet, an upper iron core and a lower iron core are separated from each other, equipment inside the iron core is inspected or replaced, and a magnetic field is adjusted. However, when the refrigerator port is provided at the upper surface or the lower surface of the iron core, handling of a refrigerant circulation hose and a power supply cable connected to the refrigerator port becomes a problem. By removing the hose and the cable from the main electromagnet, it is possible to divide and maintain the iron core-equipped superconducting magnet. However, when the hose and the cable are removed from the refrigerator port, the main coil cannot be kept at a predetermined temperature, the temperature of the main coil rises, and it takes time to resume the operation of the accelerator after maintenance work. When the accelerator including the iron core-equipped superconducting magnet is used in a particle beam therapy apparatus, the treatment efficiency decreases as the restart time after maintenance work becomes longer, which adversely affects hospital management.

The present disclosure provides an iron core-equipped superconducting magnet capable of efficiently protecting a refrigerator port portion.

### Solution to Problem

In order to solve the above problems, an iron core-equipped superconducting magnet according to the invention includes: an iron core; a coil portion vacuum chamber that is provided inside the iron core and in which a main coil is built; a refrigerator port portion provided in the iron core, the refrigerator port portion including a body portion provided to be exposed on a surface of the iron core, and a cold head portion extending from the body portion through the iron core to the main coil and connected to the main coil. A magnetic shield portion is provided between the body portion and the cold head portion, and the cold head portion is provided passing through the magnetic shield portion.

### Advantageous Effects of Invention

According to the invention, a body portion of a refrigerator port portion can be protected by a magnetic shield portion.

### BRIEF DESCRIPTION OF DRAWINGS

FIG. 1 is a top view illustrating one embodiment of an accelerator.

FIG. 2 is a side view of the accelerator.

FIG. 3 is an axial cross-sectional view of the accelerator.

FIG. 4 is an enlarged cross-sectional view of a part in FIG. 4.

FIG. 5 is a diagram schematically illustrating a state in which an upper iron core portion is displaced upward.

FIG. 6 is a diagram schematically illustrating a state in which the upper iron core portion and a coil portion vacuum chamber are displaced upward.

FIG. 7 is an overall configuration diagram of a particle beam therapy apparatus using an accelerator.

### DESCRIPTION OF EMBODIMENTS

Hereinafter, an iron core-equipped superconducting magnet and an accelerator including the iron core-equipped superconducting magnet will be described with reference to the drawings. Further, a particle beam therapy apparatus including the accelerator will also be described. In the embodiment, a refrigerator port is provided on at least one of upper and lower sides of an iron core to be as close to a main coil as possible. Further, in the embodiment, by providing a magnetic shield portion between a body portion of a refrigerator port portion and a cold head portion of the refrigerator port portion, an electric device (for example, an electric motor) built in the body portion is effectively protected from leakage flux.

Further, in the embodiment, in order to protect the refrigerator port portion with a magnetic shield portion having a minimum necessary area, a part of the iron core can be separated and displaced in an axial direction in a state where the refrigerator port portion and a compressor body are connected by a cable.

Accordingly, in the embodiment, it is possible to protect the refrigerator port portion from the leakage flux, and to divide the iron core in the axial direction and displace the iron core upward in a state where the refrigerator port portion is operated, and it is possible to perform maintenance work of the iron core-equipped superconducting magnet. After the maintenance work of the iron core-equipped superconducting magnet is completed, the iron core displaced upward is returned to its original position, and the accelerator can be operated. In the embodiment, since the maintenance work of the iron core-equipped superconducting magnet can be performed while cooling the main coil by the refrigerator port portion, the accelerator can be quickly operated again.

Therefore, with a particle beam therapy apparatus including the accelerator described in the embodiment, it is possible to extend the time for treatment and treat many patients while efficiently maintaining the iron core-equipped superconducting magnet.

The embodiment discloses devices having the following configurations.

(Expression 1) An iron core-equipped superconducting magnet including: an iron core; a coil portion vacuum chamber that is provided inside the iron core and in which a main coil is built; and a refrigerator port portion provided in the iron core, the refrigerator port portion including a body portion provided to be exposed on a surface of the iron core, and a cold head portion extending from the body portion through the iron core to the main coil and connected to the main coil, in which a magnetic shield portion is provided at a portion where the body portion is installed.

(Expression 2) The iron core-equipped superconducting magnet according to Expression 1, in which the magnetic shield portion is provided in a region where the body portion is in contact with the iron core.

(Expression 3) The iron core-equipped superconducting magnet according to Expression 2, in which the magnetic shield portion is provided as a part of the coil portion vacuum chamber.

(Expression 4) The iron core-equipped superconducting magnet according to Expression 3, further including: a case portion made of a magnetic material that covers the body portion.

(Expression 5) The iron core-equipped superconducting magnet, in which the iron core includes an upper iron core portion positioned on an axially upper side of the iron core and a lower iron core portion positioned on an axially lower side of the iron core, the coil portion vacuum chamber is positioned between the upper iron core portion and the lower iron core portion and is provided inside the iron core, the refrigerator port portion is provided in at least one of the upper iron core portion or the lower iron core portion, and the body portion is connected to a compressor body via a cable, and the iron core is provided such that a refrigerator port installation region where the refrigerator port portion is provided and another region are relatively displaceable in an axial direction.

(Expression 6) The iron core-equipped superconducting magnet according to Expression 5, in which the refrigerator port installation region has a plurality of first division lines extending from both sides of the refrigerator port portion to an outer edge of the iron core, and the plurality of first division lines are formed up to a second division line provided in an axial direction of the iron core.

(Expression 7) The iron core-equipped superconducting magnet according to Expression 6, in which when the refrigerator port portion installation region and the other region are relatively displaced in the axial direction, a passage portion through which the cable passes is formed on a side surface of the iron core along a direction parallel to the axial direction.

(Expression 8) The iron core-equipped superconducting magnet according to Expression 7, in which the refrigerator port portion is provided in the upper iron portion and the lower iron portion.

(Expression 9) The iron core-equipped superconducting magnet according to Expression 8, in which the second division line is set at a position where the upper iron core portion is displaced to an axially upper side.

(Expression 10) The iron core-equipped superconducting magnet according to Expression 8, in which the second division line is set at a position where the upper iron core portion and the coil portion vacuum chamber are displaced to an axially upper side.

(Expression 11) The iron core-equipped superconducting magnet according to Expression 8, in which the second division line includes an upper second division line set at a position where the upper iron core portion is displaced to an axially upper side and a lower second division line set at a position where the upper iron core portion and the coil portion vacuum chamber are displaced to the axially upper side.

(Expression 12) The iron core-equipped superconducting magnet according to Expression 9, further including: an elevating member, in which a cylinder body of the elevating member is attached to the lower iron portion, and a rod provided in the cylinder body in a retractable manner is attached to the upper iron portion.

(Expression 13) An accelerator including: the iron core-equipped superconducting magnet according to any one of Expressions 1 to 12.

(Expression 14) A particle beam therapy apparatus including: an irradiation device configured to irradiate a target with a beam accelerated by the accelerator according to Expression 13; and a control device configured to control the accelerator and the irradiation device.

### Embodiment 1

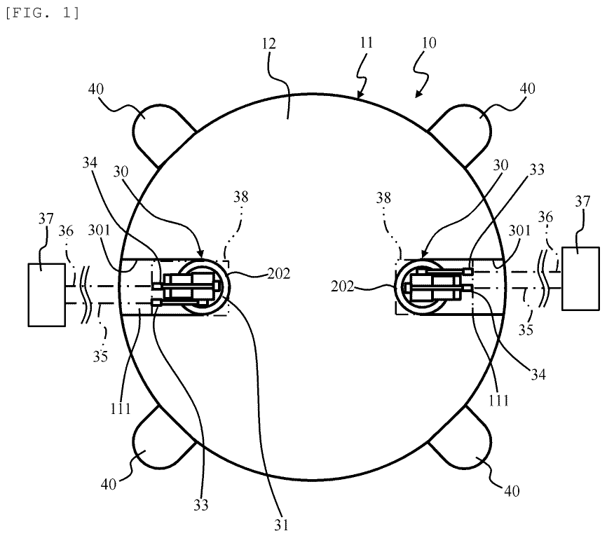

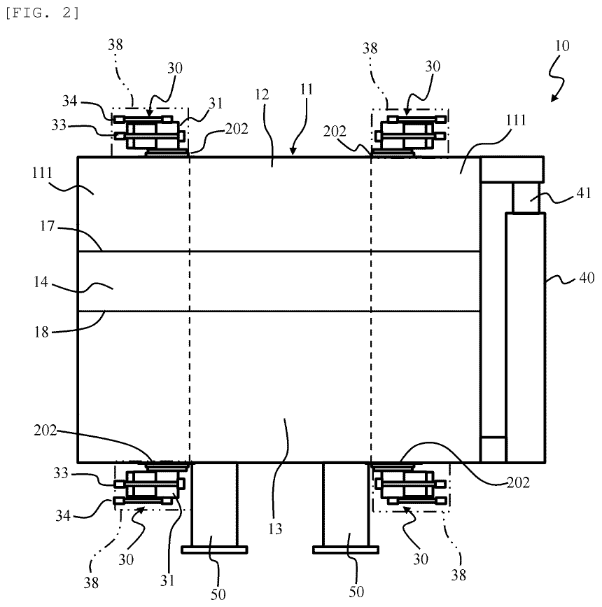

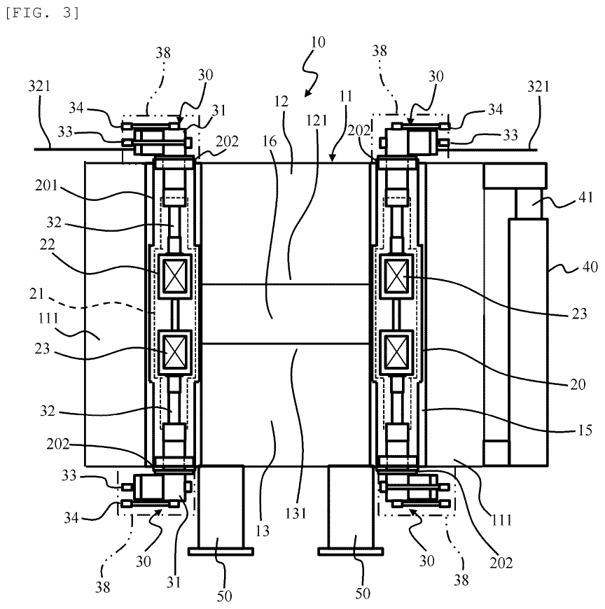

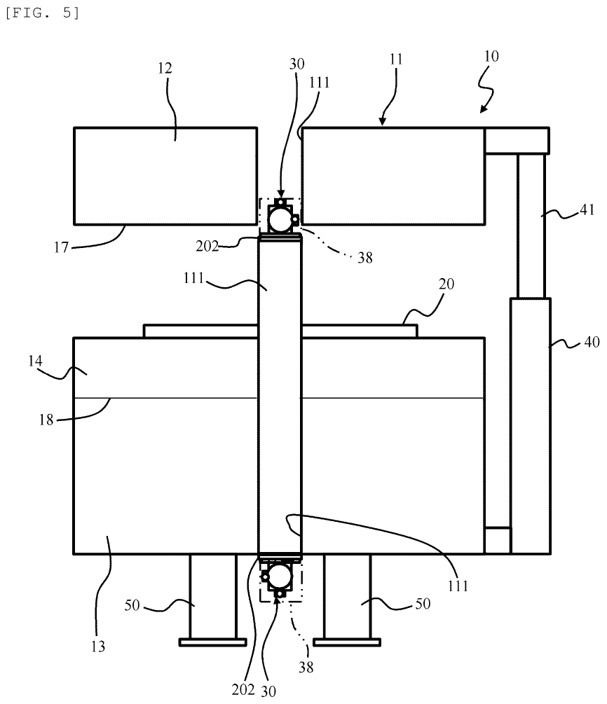

A first embodiment will be described with reference to FIGS. 1 to 7. FIG. 1 is a top view of an accelerator 10. FIG. 2 is a side view of the accelerator 10. FIG. 3 is an axial cross-sectional view of the accelerator 10.

A total of four elevating members 40 may be provided on an outer peripheral side of a main electromagnet 11 at intervals of 90 degrees, or a total of three elevating members 40 may be provided on the outer peripheral side of the main electromagnet 11 at intervals of 120 degrees. Alternatively, five or more elevating members 40 may be provided on the outer peripheral side of the main electromagnet 11.

The accelerator 10 of the embodiment is, for example, a variable energy accelerator of a frequency modulation type. The accelerator 10 is a circular accelerator that has a temporally constant magnetic field as a main magnetic field and accelerates ions (protons, carbon), which circulate in the main magnetic field, by a high-frequency electric field.

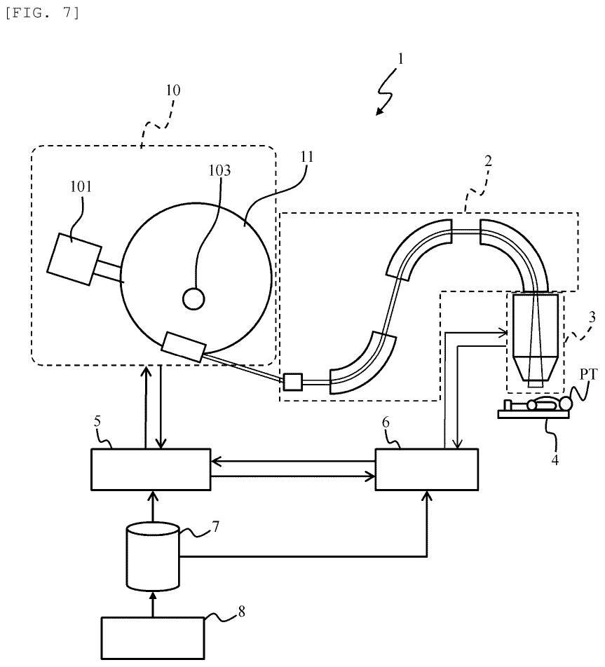

The accelerator 10 includes a high-frequency acceleration cavity 101 (see FIG. 7) that forms an acceleration electric field for accelerating ions, a rotary variable capacitor (not shown) for modulating the frequency of the acceleration electric field, an additional magnetic field generating shim (not shown) that applies a kick action from a stable region to ions circulating by a magnetic field formed by a magnetic pole 121 (see FIG. 3), a disturbance electrode (not shown) that generates a disturbance electric field for extracting, from the accelerator 1, ions to which the kick action is applied by the additional magnetic field generating shim, a low-level radio frequency generator (not shown) that controls the acceleration electric field, and a disturbance radio frequency control device (not shown) that controls the disturbance electric field. The accelerator 10 has a region in which annular circulating trajectories of a plurality of ions having different energy are aggregated and a region in which the annular circulating trajectories of the plurality of ions are dispersed, and ions enter in different cycles circulate simultaneously with substantially the same energy.

The main electromagnet 11 of the accelerator 10 is provided with a plurality of refrigerator ports 30 and a plurality of elevating members 40. A plurality of (for example, two) refrigerator ports 30 as an example of the “refrigerator port portion” are provided on each of an upper surface side and a lower surface side of the main electromagnet 11. As described above, the plurality of elevating members 40 are provided apart from each other on the outer peripheral side of the main electromagnet 11. A plurality of support legs 50 are provided on the lower surface side of the main electromagnet 11. The main electromagnet 11 is supported on a floor (not shown) by the support legs 50. The refrigerator port 30 and the elevating member 40 will be further described later.

The main electromagnet 11 of the accelerator 10 includes, for example, an upper iron core portion 12 positioned on an axially upper side, a lower iron portion 13 positioned on an axially lower side, and an intermediate portion 14 positioned between the upper iron core portion 12 and the lower iron portion 13. The intermediate portion 14 is positioned outside a coil portion vacuum chamber 20 described later. An axially upper division line 17 as an “upper second division line” is provided between the upper iron core portion 12 and the intermediate portion 14. An axially lower division line 18 as a “lower second division line” is provided between the lower iron portion 13 and the intermediate portion 14.

The intermediate portion 14 can be fixed to an upper iron portion 12 by a coupling member (not shown). In this case, when the upper iron portion 12 is lifted by the plurality of elevating members 40, the intermediate portion 14 rises together with the upper iron portion 12. Accordingly, an opening appears in the main electromagnet 11 along the axially lower division line 18, and an operator can perform maintenance work for an inner portion of the main electromagnet 1.

Examples of the maintenance work include measurement of a magnetic field in the main electromagnet 11, adjustment of a magnetic field correction device (not shown) based on a measurement result of the magnetic field, and inspection or replacement of a device (not shown) such as a high-frequency kicker.

As described later, a part of the upper iron core portion 12 and a part of the lower iron core portion 13 are separated to serve as a refrigerator port installation region 111 in which the refrigerator port 30 is provided. The refrigerator port installation region 111 can also be referred to as a refrigerator port installation portion 111 or an iron core separation portion 111.

As illustrated in FIG. 3, main magnetic poles 121 and 131 facing each other vertically are provided at a center of the main electromagnet 11. The main magnetic pole 121 is provided at a center of a lower surface of the upper iron core portion 12, and the main magnetic pole 131 is provided at a center of an upper surface of the lower iron core portion 13. A main magnetic field is generated by the main magnetic poles 121 and 131.

A space facing the main magnetic poles 121 and 131 is a beam passage region 16 in which the ion beam circulates. A superconducting coil (main coil) 23 is provided along inner walls of the upper iron core portion 12 and the lower iron core portion 13 so as to surround the main magnetic poles 121 and 131.

Specifically, the upper superconducting coil 23 is provided on an inner peripheral surface of the upper iron core portion 12 so as to surround an outside of the main magnetic pole 121. The lower superconducting coil 23 is provided on an inner peripheral surface of the lower iron core portion 13 so as to surround an outside of the main magnetic pole 131. Each superconducting coil 23 is attached to and supported by a coil frame 22.

An outside of the coil frame 22 is surrounded by a coil portion shield plate 21. A shield plate 201 surrounding the refrigerator port 30 provided on an upper side of the main electromagnet 11 is connected to an upper side of the coil portion shield plate 21. A shield plate surrounding the refrigerator port 30 provided on a lower side of the main electromagnet 11 is connected to a lower side of the coil portion shield plate 21. The shield plate 21 prevents heat outside the shield plate 21 from being transferred to the superconducting coil 23 on an inner side of the shield plate 21.

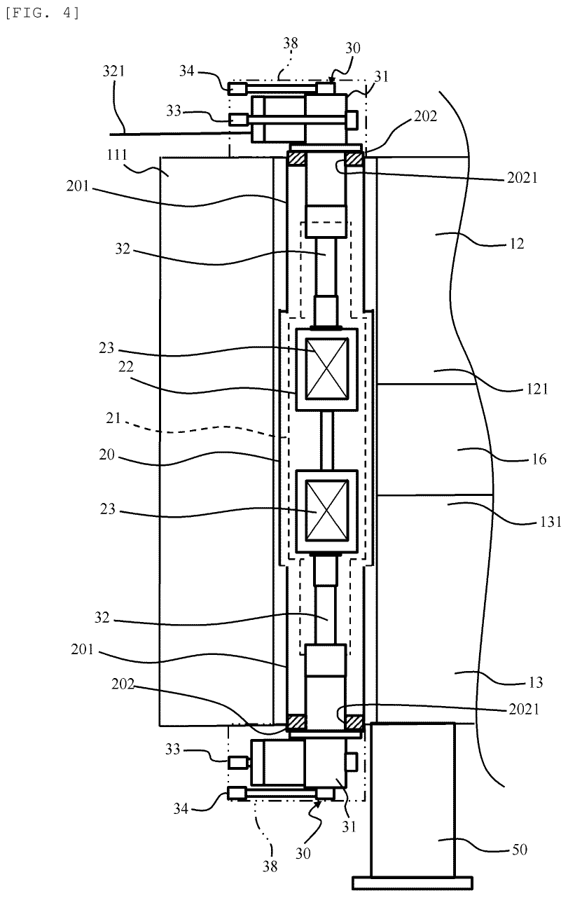

On an upper side of the shield portion 201, a magnetic shield portion 202 is provided on a flange portion on which the body portion 31 of the refrigerator port 30 is installed. The magnetic shield portion 202 is made of a magnetic material such as pure iron or SS400, is formed in a disk shape or a rectangular plate shape so as to cover a lower surface side of the body portion 31, and has a hole 2021 (see FIG. 4) through which a cold head 32 is inserted. That is, the cold head 32 passes through the magnetic shield portion 202.

As also illustrated in the enlarged view in FIG. 4, the superconducting coil 23, the coil frame 22, and the coil portion shield plate 21 are provided inside the coil portion vacuum chamber 20. The coil portion vacuum chamber 20 is also called a cryostat. The coil portion vacuum chamber 20 maintains the vacuum and temperature therein. The temperature in the coil portion vacuum chamber 20 is maintained by the cooling capacity of each refrigerator port 30.

An inside of the main electromagnet 11 is evacuated by a vacuum pump (not shown). The main electromagnet 11 is provided with a plurality of through ports for connecting the outside and the beam passage region 16. For example, a beam emission through port (not shown) for extracting an accelerated beam and a beam monitor mounting hole (not shown) for mounting a beam monitor are provided in the intermediate portion 14 of the main electromagnet 11. In addition, a through port for leading a coil conductor of the superconducting coil 23 out to the outside and a through port for inputting high-frequency power to an acceleration electrode (both ports not shown) are provided in the intermediate portion 14 of the main electromagnet 11.

A structure of a cryogenic refrigerator that cools the superconducting coil 23 of the main electromagnet 11 will be described. Reference is made to FIGS. 1 and 3. As described above, the upper iron portion 12 is provided with the two refrigerator ports 30 spaced apart from each other in a diameter direction. The lower iron portion 13 is also provided with two refrigerator ports 30 spaced apart from each other in the diameter direction.

A displacer (not shown) is built in the cold head 32 extending from the body portion 31 of each refrigerator port 30. A base end of the cold head 32 passes through the magnetic shield portion 202 and is connected to the body portion 31. A tip end of the cold head 32 contacts the coil frame 22 and cools the superconducting coil 23 in the coil frame 22 to a predetermined temperature.

The body portion 31 is provided with an electric motor for driving the displacer, a supply direction switching valve for supplying a cooling gas to the cold head 22, and a return direction switching valve for returning the cooling gas from the cold head 22 to a compressor 37 (all not shown). The electric motor is electrically connected to the compressor 37 via a cable 321 (see FIG. 3).

The body portion 31 is provided with a supply port 33 through which the cooling gas is supplied and a return port 34 through which the cooling gas is returned to the compressor 37. The supply port 33 and the compressor 37 are mechanically connected by a supply hose 35 as an example of “cables”. The return port 34 and the cooler 37 are mechanically connected by a return hose 36 as another example of “cables”. As described above, various cables 321, 35, and 36 for connecting to an external device such as the compressor 37 are connected to the refrigerator port 30 of the cryogenic refrigerator.

The body portion 31 of the refrigerator port 30 is covered with a case 38 made of a magnetic material. The body portion 31 is protected from the magnetic flux, which is generated by the superconducting coil 23, by the magnetic shield portion 202 positioned on the lower side and the case 38 positioned on the upper side.

The refrigerator port installation region 111 will be described. In the refrigerator port installation region 111, a region where the refrigerator port 30 is installed in the upper iron core portion 12 and the lower iron core portion 13 is physically separated from the rest of the iron cores, and is relatively displaceable in an axial direction (up-down direction).

The refrigerator port installation region 111 will be described by taking the upper iron core portion 12 illustrated in FIG. 1 as an example. Regarding the two refrigerator ports 30 provided so as to face each other in the diameter direction of the upper iron core portion 12, an installation portion thereof in the upper iron core portion 12 has a circular shape (plan view). First division lines 301 are provided from both sides of the circular installation portion toward an outer edge of the upper iron core portion 12. Of each circular installation portion of the refrigerator port 30, an outer edge of a semicircular portion close to a center of the upper iron core portion 12 is also divided from the rest of the iron core. That is, the installation region 111 of the refrigerator port 30 is formed in a horizontal U shape in plan view, and is divided from the rest of the iron core other than the installation region 111. The refrigerator port installation region 111 of the upper iron core portion 12 is divided from the rest of the upper iron core portion 12 up to the upper division line 17.

The magnetic shield portion 202 is present in the refrigerator port installation region 111 together with the refrigerator port 30.

Although not illustrated, the lower iron core portion 13 is also provided with two refrigerator ports 30 facing each other in the diameter direction of the lower iron core portion 13. Regarding each refrigerator port 30, an installation portion thereof in the lower iron core portion 13 has a circular shape (plan view). First division lines (not shown) are provided from both sides of the circular installation portion toward an outer edge of the lower iron core portion 13. Of each circular installation portion of the refrigerator port 30, an outer edge of a semicircular portion close to a center of the lower iron core portion 13 is also divided from the rest of the iron core. That is, the installation region 111 of the refrigerator port 30 is formed in a horizontal U shape in plan view, and is divided from the rest of the iron core other than the installation region 111. A region sandwiched between the first division lines 301 is a lead-out region of the cables 321, 35, and 36. The cable 321 and the hoses 35 and 36 are led out to the outer peripheral side along the diameter direction of the main electromagnet 11 in the region sandwiched between the first division lines 301. Therefore, even when the refrigerator port installation region 111 and the rest of the iron core are displaced in the axial direction, it is not necessary to remove the cables 321, 35 and 36 from the refrigerator port 30.

The refrigerator port installation region 111 of the lower iron core portion 13 is divided from the rest of the lower iron core portion 13 up to the lower division line 18. The configuration of each refrigerator port installation region 111 of the lower iron core portion 13 is the same as the configuration of each refrigerator port installation region 111 of the upper iron core portion 12 illustrated in FIG. 1. Even when the refrigerator port installation region 111 and the rest of the iron core are displaced in the axial direction, it is not necessary to remove the cables from the refrigerator port 30.

The elevating member 40 will be described. A plurality of elevating members 40 are provided around the main electromagnet 11, and a lower side of body portions thereof is attached to an outer peripheral surface of the lower iron core portion 13. The elevating member 40 may be an electric type, a hydraulic type, or a pneumatic type. A tip end of a rod 41 of the elevating member 40 is attached to an outer peripheral surface of the upper iron core portion 12. The elevating member 40 can displace only the upper iron core portion 12 or the upper iron core portion 12 and the intermediate portion 14 to an axially upper side of the main electromagnet 11 by extending the rod 41. By contracting the rod 41, the elevating member 40 places the upper iron core portion 12 on the intermediate portion 14 or places the upper iron core portion 12 and the intermediate portion 14 on the lower iron core portion 13. The elevating member 40 operates according to a control signal from a control device (not shown). The above-described cryogenic refrigerator (refrigerator port 30, compressor 37) also operates according to a control signal from a control device (not shown).

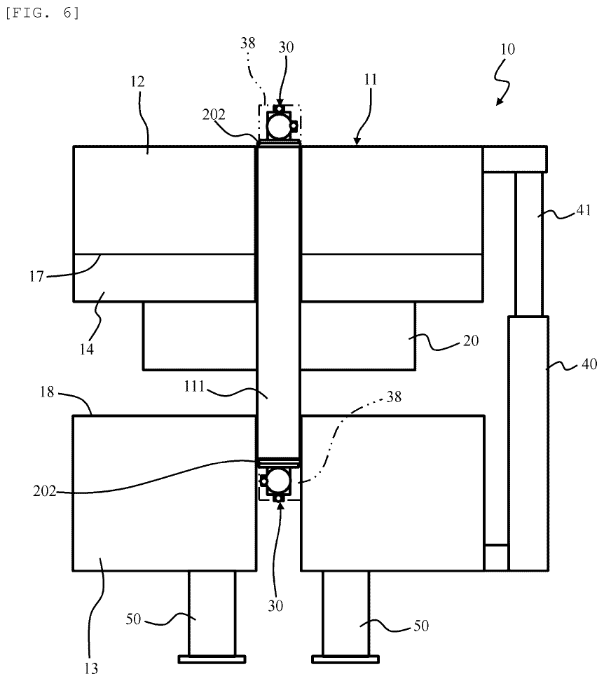

FIG. 6 schematically illustrates a state in which only the upper iron core portion 12 is displaced upward. When the coupling between the upper iron core portion 12 and the intermediate portion 14 is released and the rod 41 of each elevating member 40 is extended, the upper iron core portion 12 moves upward away from the intermediate portion 14. Since the upper iron core portion 12 and the installation region 111 in which the upper refrigerator port 30 is provided are divided, the refrigerator port installation region 111 does not follow the upward displacement of the upper iron core portion 12 and maintains its position and posture. Since the cables (electric cable, cooling gas hose) connected to the refrigerator port 30 are not displaced, it is not necessary to remove the cables from the refrigerator port 30. In other words, the shape (in plan view) of the refrigerator port installation region 111 is set such that the cables may not be removed from the refrigerator port 30. However, this description is one example, and the refrigerator port installation region 111 may be formed in another shape as illustrated in another embodiment described later.

When the upper iron core portion 12 is displaced upward, the upper side of the coil portion vacuum chamber 20 is exposed. Accordingly, the operator can perform magnetic force measurement, setting of a magnetic force adjustment device, and the like.

FIG. 6 is a diagram schematically illustrating a state in which the upper iron core portion 12 and the intermediate portion 14 (the coil portion vacuum chamber 20 held by the intermediate portion 14) are displaced upward.

The intermediate portion 14 is attached to the outside of the coil portion vacuum chamber 20. When the rod 41 of the elevating member 40 is extended in a state where the intermediate portion 14 and the upper iron core portion 12 are coupled by a coupling member (not shown), the upper iron core portion 12, the intermediate portion 14, and the coil portion vacuum chamber 20 are displaced upward. Accordingly, the operator can inspect or repair the periphery of the coil portion vacuum chamber 20.

When the upper iron core portion 12, the intermediate portion 14, and the coil portion vacuum chamber 20 are displaced upward, the refrigerator port installation region 111 maintains its position and posture as it is, and the cables connected to the refrigerator port 30 do not interfere with the upward displacement of the upper iron core portion 12, the intermediate portion 14, and the coil portion vacuum chamber 20. Therefore, it is possible to perform maintenance work by partially disassembling the main electromagnet 11 while operating the refrigerator port 30.

FIG. 7 is an overall configuration diagram of a particle beam therapy apparatus 1 using the accelerator 10. The particle beam therapy apparatus 1 includes the accelerator 10, a beam transport system 2, an irradiation device 3, a treatment table 4, an overall control device 5, an irradiation control device 6, a therapy plan database 7, and a therapy planning device 8.

The high-frequency acceleration cavity 101 forms an acceleration electric field for accelerating ions to form an ion beam, through a radio frequency power input through port (not shown). The high-frequency acceleration cavity 101 is provided with, for example, a dee electrode for acceleration and a rotary variable capacitor for modulating the frequency of an acceleration electric field (both not shown).

An ion source 103 for supplying hydrogen ions is installed at a position shifted from a center of an upper portion of the main electromagnet 11. The ion source 103 supplies ions to the beam passage region 16 inside the accelerator 10 through a beam entrance through port (not shown).

The beam transport system 2 is a mechanism that transports an ion beam (hereinafter, also referred to as a beam) accelerated by the accelerator 10 to the irradiation device 3. The irradiation device 3 is a device that irradiates a target in a patient PT fixed to the treatment table 4 with the beam transported by the beam transport system 2. The overall control device 5 controls the accelerator 10, the beam transport system 2, and the irradiation device 3. The irradiation control device 6 controls beam irradiation on a target. The therapy plan database 7 stores a therapy plan created by the therapy planning device 8. The therapy planning device 8 creates a beam irradiation plan for the target.

In the particle beam therapy apparatus 1, energy and dose of the particle beam for irradiation are determined by therapy planning. The energy and dose of the particle beam determined by the therapy planning are sequentially input from the overall control device 5 to the irradiation control device 6. When the target is irradiated with an appropriate dose, the particle beam therapy apparatus 1 shifts to the next energy and irradiates the target with the beam again.

According to the particle beam therapy apparatus 1 configured as described above, since the accelerator 10 described above is provided, the maintenance work of the main electromagnet 11 can be performed while each refrigerator port 30 is operated, and the time for treating the patient can be increased.

According to the embodiment configured as described above, since the magnetic shield portion 202 is provided between the body portion 31 and the cold head 32 of the refrigerator port 30, it is possible to restrict the influence of the leakage flux from the superconducting coil 23 on the electric devices in the body portion 31.

Further, in the embodiment, since the body portion 31 is covered with the case 38 made of a magnetic material, the magnetic shield portion 202 and the case 38 can protect the body portion 31 from the leakage flux.

According to the embodiment, in the iron core-equipped superconducting magnet 11 that cools the superconducting coil 23 by bringing the refrigerator port 30 close to the superconducting coil 23 from above the iron core 12 and below the iron core 13, since the iron cores 12 and 13 are provided such that the refrigerator port installation region 111 in which the refrigerator port 30 is provided and the other region are relatively displaceable in the axial direction, it is possible to perform maintenance work of the main electromagnet 11 while operating the refrigerator port 30.

In the embodiment, when the refrigerator port installation region 111 and the other region are relatively displaced in the axial direction, a passage portion through which cables pass is formed on the side surface of the iron core along a direction parallel to the axial direction. Therefore, even when a part of the iron core is separated and displaced in the axial direction, the cables of each refrigerator port 30 can be prevented from interfering with the iron core or the like, and the maintenance work of the main electromagnet 11 can be performed while each refrigerator port 30 is operated.

In the embodiment, as illustrated in FIG. 1, since two refrigerator ports 30 are provided facing each other in the diameter direction of the main electromagnet 11, the superconducting coil 23 can be uniformly cooled. Further, in the embodiment, as illustrated in FIG. 3, the refrigerator ports 30 passing through the upper iron core portion 12 and the refrigerator ports 30 passing through the lower iron core portion 13 are arranged on a straight line in the axial direction. Therefore, the overall configuration can be simplified.

A line connecting the two refrigerator ports 30 passing through the upper iron core portion 12 in the axial direction (a line in the diameter direction of the main electromagnet 11. The same applies hereinafter) and a line connecting the two refrigerator ports 30 passing through the lower iron core portion 13 in the axial direction may be set at different angles. For example, the line connecting the refrigerator ports 30 on the upper side and the line connecting the refrigerator ports 30 on the lower side may be set to be different by a predetermined angle such as 90 degrees.

In the embodiment, since the superconducting coil 23 is cooled by bringing the refrigerator port 30 close to the superconducting coil 23 from above the iron core 12 and below the iron core 13, a dimension of the main electromagnet 11 in a radial direction can be reduced, and the area required for installing the accelerator 10 can be reduced. For example, when the refrigerator port is inserted from the radial direction of the main electromagnet as in PTL 2, a radial dimension of the accelerator increases, and thus the area required for installation also increases, and the installation cost also increases. In contrast, in the embodiment, since the refrigerator port 30 is attached from the up-down direction of the main electromagnet 11, the dimension of the accelerator 10 in the radial direction can be reduced, the area required for installation of the accelerator 10 can be reduced, and the installation cost can be reduced.

In the embodiment, since a total of four refrigerator ports 30 are arranged, two above and two below the main electromagnet 11, even when any one of the refrigerator ports 30 fails, the superconducting coil 23 can be maintained at a predetermined temperature by the other three refrigerator ports 30 by adjusting the setting of the cooling capacity.

In the embodiment, since the lower side of the body portion 31 of the refrigerator port 30 is protected by the magnetic shield portion 202 and the iron core 111 in the region where the refrigerator port 30 is installed is separated from the rest of the iron core, it is possible to protect the body portion 31 of the refrigerator port 30 from the leakage flux and vertically separate the iron cores while operating the refrigerator port 30.

In the embodiment, since the cold head 32 passes through the magnetic shield portion 202, the body portion 31 can be brought close to the surface of the iron core. Accordingly, a length dimension from the cold head 32 to the superconducting coil 23 can be reduced, and the superconducting coil 23 can be efficiently cooled. On the other hand, if the magnetic shield portion is not provided on the lower side of the body portion 31, it is necessary to keep the cold head 32 away from the superconducting coil 23 in order to protect the electric devices in the body portion 31 from the leakage flux of the superconducting coil 23. However, when the cold head 32 is moved away from the superconducting coil 23, the superconducting coil 23 cannot be efficiently cooled.

The invention is not limited to the above-described embodiments. Those skilled in the art can perform various additions, modifications, or the like within the scope of the invention. The above-described embodiments are not limited to the configuration examples illustrated in the accompanying drawings. The configurations and the processing methods of the embodiments can be appropriately changed within 2 range of achieving the object of the invention. For example, the shape of the refrigerator port installation region is not limited to the illustrated shape.

In addition, components of the invention can be freely selected, and an invention including the selected components is also included in the invention. Further, the configurations described in the claims can also be combined in addition to the combinations described in the claims.

### REFERENCE SIGNS LIST

1: particle beam therapy apparatus
2: beam transport system
3: irradiation device
4: treatment table
5: overall control device
6: irradiation control device
7: therapy plan database
8: therapy planning device
10: accelerator
11, 11A, 11B: main electromagnet
12: upper iron core portion
13: lower iron core portion
14: intermediate portion
20: coil portion vacuum chamber
23: superconducting coil
30: refrigerator port
31: body portion
32: cold head
35, 36: cooling gas hose
38: case
40: elevating member
111: refrigerator port installation region
202: magnetic shield portion
301: first division line
321: power supply cable

1. An iron core-equipped superconducting magnet comprising:
an iron core;
a coil portion vacuum chamber that is provided inside the iron core and in which a main coil is built; and
a refrigerator port portion provided in the iron core, the refrigerator port portion including a body portion provided to be exposed on a surface of the iron core, and a cold head portion extending from the body portion through the iron core to the main coil and connected to the main coil, wherein
a magnetic shield portion is provided between the body portion and the cold head portion, and the cold head portion is provided passing through the magnetic shield portion.

2. The iron core-equipped superconducting magnet according to claim 1, wherein
the magnetic shield portion is provided as a part of the coil portion vacuum chamber.

3. The iron core-equipped superconducting magnet according to claim 2, further comprising:
a case portion made of a magnetic material that covers the body portion.

4. The iron core-equipped superconducting magnet according to claim 1, wherein
the iron core includes an upper iron core portion positioned on an axially upper side of the iron core and a lower iron core portion positioned on an axially lower side of the iron core,
the coil portion vacuum chamber is positioned between the upper iron core portion and the lower iron core portion and is provided inside the iron core,
the refrigerator port portion is provided in at least one of the upper iron core portion or the lower iron core portion, and the body portion is connected to a compressor body via a cable and a hose, and
the iron core is provided such that a refrigerator port installation region where the refrigerator port portion is provided and another region are relatively displaceable in an axial direction.

5. The iron core-equipped superconducting magnet according to claim 4, wherein
the refrigerator port installation region has a plurality of first division lines extending from both sides of the refrigerator port portion to an outer edge of the iron core, and the plurality of first division lines are formed up to a second division line provided in an axial direction of the iron core.

6. The iron core-equipped superconducting magnet according to claim 5, wherein
when the refrigerator port portion installation region and the other region are relatively displaced in the axial direction, a passage portion through which the cable and the hose pass is formed on a side surface of the iron core along a direction parallel to the axial direction.

7. The iron core-equipped superconducting magnet according to claim 6, wherein
the refrigerator port portion is provided in the upper iron portion and the lower iron portion.

8. The iron core-equipped superconducting magnet according to claim 7, wherein
the second division line is set at a position where the upper iron core portion is displaced to an axially upper side.

9. The iron core-equipped superconducting magnet according to claim 7, wherein
the second division line is set at a position where the upper iron core portion and the coil portion vacuum chamber are displaced to an axially upper side.

10. The iron core-equipped superconducting magnet according to claim 7, wherein
the second division line includes an upper second division line set at a position where the upper iron core portion is displaced to an axially upper side and a lower second division line set at a position where the upper iron core portion and the coil portion vacuum chamber are displaced to the axially upper side.

11. The iron core-equipped superconducting magnet according to claim 8, further comprising:
an elevating member, wherein
a cylinder body of the elevating member is attached to the lower iron portion, and a rod provided in the cylinder body in a retractable manner is attached to the upper iron portion.

12. An accelerator comprising:
the iron core-equipped superconducting magnet according to claim 1.

13. A particle beam therapy apparatus comprising:
an irradiation device configured to irradiate a target with a beam accelerated by the accelerator according to claim 12; and
a control device configured to control the accelerator and the irradiation device.
